(19) United States
(12) Patent Application Publication
(10) Pub. No.: US 2023/0349683 A1
(43) Pub. Date: Nov. 2, 2023

(54) METHOD AND DEVICE FOR LINE PROTECTION

(71) Applicant: ARCTEQ RELAYS OY, Vaasa (FI)

(72) Inventor: Tero VIRTALA, Vaasa (FI)

(21) Appl. No.: 17/914,048

(22) PCT Filed: Mar. 25, 2020
(86) PCT No.: PCT/FI2020/050185

§ 371 Date: Sep. 23, 2022

(51) Int. Cl. G01B 7/02; G01R 31/08; H02H 1/00

(52) U.S. Cl. CPC G01B 7/026; G01R 31/08; H02H 1/0038; H02H 1/0061

(57) ABSTRACT

Disclosed is a method for determining the distance to a fault location of a power line to be protected in an electric power system, the method including: configuring the power line to be protected into a plurality of segments, obtaining a plurality of line settings separately for each of the plurality of segments configured, and using the line settings obtained to determine a fault location of the power line to be protected, wherein the line settings include at least one of impedance, resistance, reactance, length, compensation factor, angle. Also disclosed is an intelligent electronic device.

### TECHNICAL FIELD

The invention relates to a distance relay and a method used for controlling a distance relay for protecting an electric power line in a power transmission or distribution system.

### BACKGROUND

As known, a distance relay, also referred as Intelligent Electronic Device, is a device used to control and protect overhead lines and cables and designed to trip the circuit breaker when a fault or abnormal condition is detected in the protection zone of the power grid. More particularly, the purpose of the distance relays is to determine based on the zone impedance settings whether there is a fault within zone or out-of-zone, and further to determine the positive sequence impedance up to the fault position as accurately as possible, by measuring voltages and currents at relay location.

To accomplish this the user can control the relay settings via the distance relay interface by setting the line parameters according to the power line configuration. Therefore, the reach setting for each phase and ground zone of a distance relay is set based solely on positive sequence impedance between the relay and the endpoint of the line to protect. In case of phase faults, the aforementioned setting is adequate for the relay to locate the fault accurately. However, as power systems constantly evolve with changes in line configurations, this reach setting cannot guarantee correct operation of the conventional distance relays, as the line impedance is not always kept constant.

### SUMMARY

An object of the present disclosure is to provide a solution by means of which the accuracy and reliability of fault location in distance protection relays may be improved in relation to the solutions of the prior art.

The object of the disclosure is achieved by a distance protection relay and a method which is characterized by what is stated in the independent claims. The preferred embodiments of the disclosure are presented in the dependent claims.

The invention relates to a method for determining the distance to a fault location of a power line to be protected in an electric power system, wherein the method comprises steps of configuring the power line to be protected into a plurality of segments, obtaining a plurality of line settings separately for each of the plurality of segments configured, and using the line settings obtained to determine a distance to fault location of the power line to be protected, wherein the line settings include at least one of impedance, resistance, reactance, length, compensation factor, angle.

The invention relates also to a method for configuring an intelligent electronic device to protect a power line of an electric power system, wherein the configuring comprising steps of receiving, in the intelligent electronic device, a first user input to select whether the protected power line is configured with a non-segmented configuration having a single protection segment or a segmented configuration having a plurality of protection segments, identifying a selection corresponding to the first user input, based on the identifying, provided that the selection is a segmented configuration, determining the impedances of the segments of line to be protected, and calculating the impedance of the line based on the sum of the determined impedances.

The invention relates also to an intelligent electronic device for protecting of a power line of an electric power system and switching device comprising an intelligent electronic device.

### BRIEF DESCRIPTION OF THE DRAWINGS

In the following the invention is described in detail with reference to the accompanying drawings, in which

FIG. 1 shows a distance protection system to which the embodiments of the invention may applied,

FIG. 2 shows an example of phase to earth fault loop according to prior art,

FIG. 3 shows an example of zone in quadrilateral R/X diagram according to prior art,

FIG. 4 shows a distance protection system to which the embodiments of the invention may applied,

FIG. 5 shows a comparison between a method according to the prior art and a method according to embodiments of the invention with reference to the examples shown in the FIG. 4,

FIG. 6 shows a comparison between a method according to the prior art and a method according to embodiments of the invention with reference to the examples shown in the FIG. 4,

FIG. 7 shows an example of a circuit diagram using a method according to embodiments of the invention,

FIG. 8 shows an example of a circuit diagram using a method according to embodiments of the invention,

FIG. 9 shows an example of quadrilateral R/X diagram using a method according to embodiments of the invention.

### DETAILED DESCRIPTION OF THE INVENTION

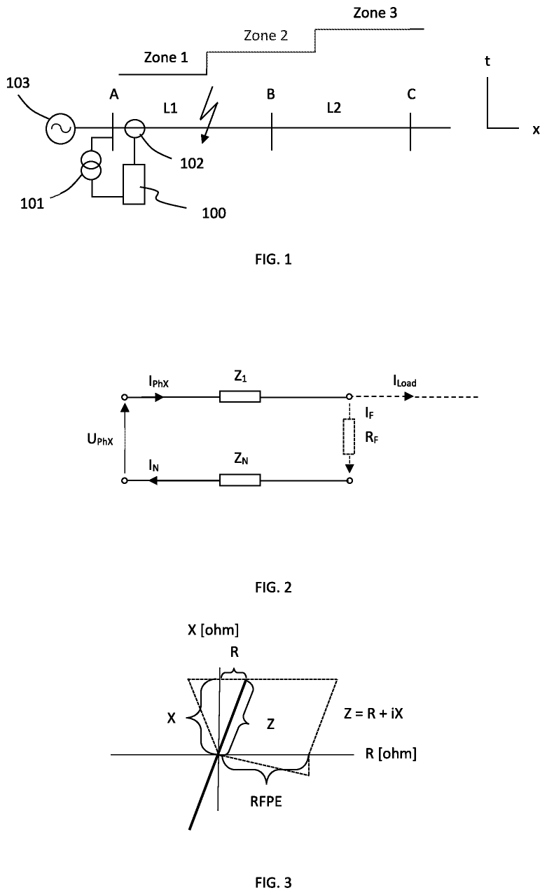

FIG. 1 shows a distance protection system to which embodiments of the invention may be applied. In FIG. 1, there is a power generator 103 connected by the first section of 120 km (for example) single power (transmission) line L1 between substation A and substation B followed by the second section of 100 km (for example) single power (transmission) line L2 between substation B and substation C. Voltage and current signals by the VT 101 and CT 102, respectively, are applied to the distance (protection) relay 100. Zone 1 is set to cover, for example, 100 km of power transmission line L1. Zone 2 covers remaining part of L1 plus 50% length of L2, and zone 3 covers the remaining portion of L2, for example. The distance relay may be an intelligent electronic device (IED) which may be a microcontroller based, having an algorithm or a program by means of which the IED is capable of controlling and processing a wide variety of mathematical or non-mathematical functions, such as current and voltage measurements, control of switching devices such as control of circuit breakers calculation and performing data analysis based on the data received. However, an embodiment is not limited IEDs only and may also be possibly implemented in other relay devices. The IED is may be provided by a user interface having a keyboard, an operating panel, a display and/or a touchscreen arranged therein.

To measure impedance, the relay requires continuous current and voltage measurements, from the feeder current and the voltage transformers. The impedance is calculated using the following formula:

$$\overline{u} = R \cdot \overline{ι} + \frac{X}{{ω}_{0}} \cdot \frac{Δ \overline{ι}}{Δ t}$$

where ū is the momentary measured voltage, ī is the momentary measured current and ω₀=2·π·f₀ is the angular frequency. R is the resistance and X the reactance of the line. The expression Δī/Δt describes the change in momentary current divided by the change in time. This can be rewritten as a complex formula:

$$Re ( \overline{u} ) = R \cdot Re ( \overline{ι} ) + \frac{X}{{ω}_{0}} \cdot \frac{ΔRe ( \overline{ι} )}{Δ t}$$

$$Im ( \overline{u} ) = R \cdot Im ( \overline{ι} ) + \frac{X}{{ω}_{0}} \cdot \frac{ΔIm ( \overline{ι} )}{Δ t}$$

And as such we can extract the resistance and the reactance as the two main components of impedance.

$$R = \frac{Im ( \overline{u} ) \cdot ΔRe ( \overline{ι} ) - Re ( \overline{u} ) \cdot Im ( \overline{ι} )}{ΔRe ( \overline{ι} ) \cdot Im ( \overline{ι} ) - ΔIm ( \overline{ι} ) \cdot Re ( \overline{ι} )}$$

$$X = {ω}_{0} \cdot Δ t \cdot \frac{Re ( \overline{u} ) \cdot Im ( \overline{ι} ) - Im ( \overline{u} ) \cdot Re ( \overline{ι} )}{ΔRe ( \overline{ι} ) \cdot Im ( \overline{ι} ) - ΔIm ( \overline{ι} ) \cdot Re ( \overline{ι} )}$$

And as such we can calculate the impedance Z as:

Z=R+iX

To calculate the impedance for faults, either loop or phase domain calculations may be utilized. An example circuit diagram, based on the loop domain method, is shown in FIG. 2. In a phase to earth fault with no load the impedance is calculated, using the loop domain method, by the following formula:

$${Z}_{P h - E} = \frac{{U}_{P h X}}{{I}_{P h X}} = {Z}_{1} + {Z}_{N} + {R}_{F} ,$$

wherein Uₚₕₓ and I_{Phx} represents the voltage and current measured for the faulted phase, Z₁ is the positive-sequence impedance of the protected line until the point of the fault, I_{load} is the load component, R_{F} is the fault resistance (resistance between phase and earth at fault location) and I_{F} is the current through that resistance R_{F}. Z_{N} is the return path impedance and is defined as Z_{N}=(Z_{O}−Z₁)/3 where Z₀ is the zero-sequence impedance of the line.

The protection zones are defined by impedance Z and illustrated in an R/X diagram, with the resistance on the real part of the axis and the reactance on the imaginary part of the axis, as is shown in FIG. 3. FIG. 3 shows an example of the phase to earth zone (denoted by a dotted line in FIG. 3), having set values (positive sequence resistive reach R, positive sequence reactive reach X, resistive reach of phase to earth loops RFPE) for phase to earth faults and phase to phase faults and is limited to only reach forward by angles defined by the set values maximum and minimum phase angle which defines maximum angle from R-axis to right hand side of directional line and left.

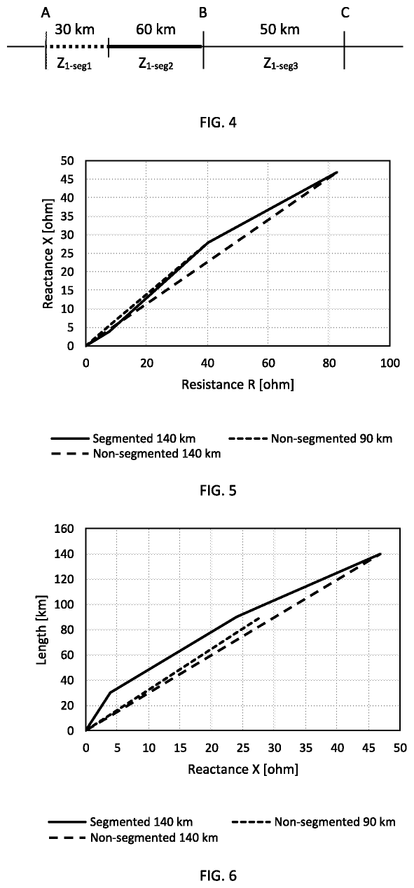

Let us now describe embodiments of the invention with reference to FIGS. 4-9. FIG. 4 shows, by way of example, a distance protection scenario to which embodiments of the invention may be applied. In FIG. 4, there is presented a power transmission line with three substations, denoted by A (substation A), B (substation B) and C (substation C), in which power line, a distance protection relay, such as an IED, is arranged (not shown in FIG. 4). Between the two substations A and B, the power line has a length of 90 km and a total line resistance of R=40.2 ohms and a total line reactance of X=27.9 ohms. Between substations B and C, the line length is 50 km, giving a total protected line of 140 km. Between substations A and B, the power line has two segments, i.e. two subdivisions of the power line to be protected by the IED, which segments do not overlap, in this case, the first segment having a length of 30 kilometers, with a resistance of 0.26 ohms per kilometer and a reactance of 0.13 ohms per kilometer. The second segment has a length of 60 kilometers, a resistance of 0.54 ohms per kilometer, and a reactance of 0.40 ohms per kilometer. Between the substations B and C, the line has only one segment with a length of 50 kilometers, a resistance of 0.85 ohms per kilometer, and a reactance of 0.38 ohms per kilometer.

In the segmented configuration, as described above, it is assumed, that the impedance of the line to be protected may vary over the zone to protected, in accordance with the segment impedances, with R and X, as is the case of FIG. 4. In general, the segmented configuration disclosed in the present invention may be used, when the line type changes, for example, from underground cables to overhead lines, or the environment, such as soil, changes along the line length or in line segments. In this context, a non-segmented configuration means that the line to be protected is not divided into segments, whereby, for example, line type changes or ground changes are not considered. In principle, when the non-segmented configuration is selected, it is assumed that the line is homogeneous, and that the ratio of impedance unit to line length unit remains unchanged over the length of the line or zone to be protected. Correspondingly, when a segmented configuration is selected, it is assumed that the line may be heterogeneous, whereby the ratio of the impedance unit to the line length unit may change over the length of the line or a zone to be protected.

Referring to the scenario shown in FIG. 4, in order to configure the IED for line protection, the user provides the line settings to the IED using a keyboard or a touch screen arranged therein. Upon receiving the first user input the IED is configured to identify a selection corresponding to the first user input. The first user input may contain, for example, information about the configuration type and number of the plurality of segments applied in the distance protection scenario to be configured. This is accomplished in an embodiment by configuring the IED to divide the line to be protected into a plurality of segments. Based on the identifying, provided that the selection is a segmented configuration, the IED is configured to determine the impedances for each of the segments of line to be protected. The step of determining the impedances of the plurality of segments may also comprise a step, wherein the IED is configured to receive, a second user input for selecting a plurality of line settings for each of the plurality of segments, identifying the line settings corresponding to the second user input.

In response to the selection by the user, the intelligent electronic device is configured to display a view of a configuration selected, wherein said configuration comprises a list, or a table, of a plurality of segments of the line to be protected. The view in the IED may also be configured to prompt the user to provide a second user input for selecting a plurality of line settings separately for each of the plurality of segments involved for the user's selection. The line settings may include relay parameters comprising at least one of impedance Z, resistance R, reactance X, length, compensation factor, and angle.

For configuring the IED, the IED may comprise a specific tool, such as a line protection module, a user interface, a control panel, a software program or a human machine interface panel, for selecting appropriate relay parameters of the line settings according the user's preference. By means of the specific tool, the user may be provided for setting the line settings, or parameters, separately for each line to be protected, for example, for zero sequence line settings and positive sequence line settings. Said tool, or interface, may include for example, setting of relay parameters for the number of segments applied in the line configuration, setting length for each of the segments applied, setting resistance for each of the segments selected and setting reactance for each of the segments selected, compensation factors for each of the segments selected. For example, for the positive sequence line settings, the user can choose between a segmented configuration or a non-segmented configuration. If the user selects a segmented configuration, the user can further select and set the number of segments of the segmented configuration, for example, to determine whether the segments are the same length or different lengths, and to set values separately for each segment including, for example segment length, correction factor, segment resistance and segment reactance. Similarly, the user can determine and set the line settings for the zero sequence line settings.

Based on the configuration, the IED is configured to calculate the impedance based into the given line settings and parameter values, as a sum of the impedances determined for each of the segments.

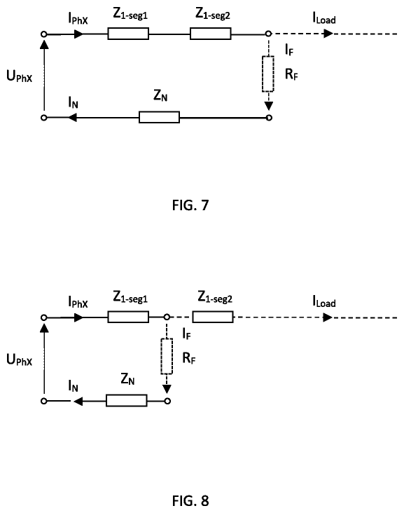

To calculate the impedance for faults, in a segmented configuration, in case there are two segments until to the fault, the calculation of the fault impedance can be done as shown in FIG. 7. In a phase to earth fault with no load the impedance is calculated, using the loop domain method, by the following formula:

$${Z}_{P h - E} = \frac{{U}_{P h X}}{{I}_{P h X}} = {Z}_{1 - seg 1} + {Z}_{1 - seg 2} + {Z}_{N} + {R}_{F ,}$$

wherein Uₚₕₓ and I_{Phx} represents the voltage and current measured for the faulted phase, Z_{1-seg1} and Z_{1-seg2} are the positive-sequence impedances of the protected line until the point of the fault, I_{load} is the load component, R_{F} is the fault resistance (resistance between phase and earth at fault location) and I_{F} is the current through that resistance R_{F}.

FIG. 8 illustrates a situation in which a fault is between two segments: Z_{1-seg1} and Z_{1-seg2} It can be noticed from FIG. 8 that the segmented method provides the ability to obtain more accurate fault distance positioning than the conventional non-segmented (conventional) method. In a phase to earth fault with no load the impedance is then calculated, using the loop domain method, by the following formula:

$${Z}_{P h - E} = \frac{{U}_{P h X}}{{I}_{P h X}} = {Z}_{1 - seg 1} + {Z}_{N} + {R}_{F} ,$$

Instead of conventionally determining the impedance Z_{Ph-E} based on Z₁, based on non-segmented method, it can now be determined based on a line segment impedance Z_{1-seg1}, i.e. based on segmented method.

When comparing the conventional (non-segmented) method with the segmented method for setting ground or zero sequence compensation for a power line, in the conventional way of distance protection, only one compensation factor is applied to the distance relay. In conventional method, it is assumed that the entire power line to be protected is homogeneous, including the ground resistivity factors and the power line itself. By the segmented method of the present disclosure, the compensation (or correction) factors can be set separately for each segment. On a segmented configuration of the power line, the distance zone can be thought of as kilometers (or any unit of length) from a relay point, and the reactive reach can also be set in this way. For example, in the distance protection scenario shown in FIG. 4 above, the user can set the line settings between the substations A and B for each segments, in kilometers (in length units), 30 kilometers for the first segment, and 60 kilometers for the second segment. In addition, according to the present disclosure, the heterogeneous ground resistivity can be properly compensated for when the line type changes, for example, from ground-dug cables to the overhead line, or the ground type changes significantly in length or portions of the protected line.

In FIGS. 5 and 6 comparisons between a conventional (non-segmented) and a segmented method according to the present disclosure are presented.

FIG. 5 shows a comparison in which the distance protection scenario shown in FIG. 4 is implemented by applying a non-segmented and a segmented configuration method for setting line settings. It can be seen from FIG. 5 that in the segmented method (solid black line), the impedance between the substations A and C is determined by the combination of the impedances of the segments, as a result of the sum of vectors. The two separate dashed lines represent the non-segmented impedance calculation, separately between the substations A and B and between the substations B and C.

FIG. 6 shows a comparison in the X/length diagram, where the scenario shown in FIG. 4 is implemented by applying a non-segmented and a segmented configuration method for setting line settings. The two separate straight lines represented by the dashed line represent the non-segmented impedance calculation, separately between the substations A and B and between the substations B and C.

From FIGS. 5 and 6, it can be noticed that the IED, in which the power line is configured in a plurality of segments, has more accurate information of the line when compared with the non-segmented configuration. The segmented configuration thereby increases significantly the accuracy of the fault location as well as the accuracy of the resistive reach for the actual protection zones in the relay. The difference between the method of setting the line by the present disclosure, i.e. segmented configuration method, vs. conventional average calculated method, i.e. non-segmented configuration method, is even more significant when the earth fault factor calculation is added into the equation.

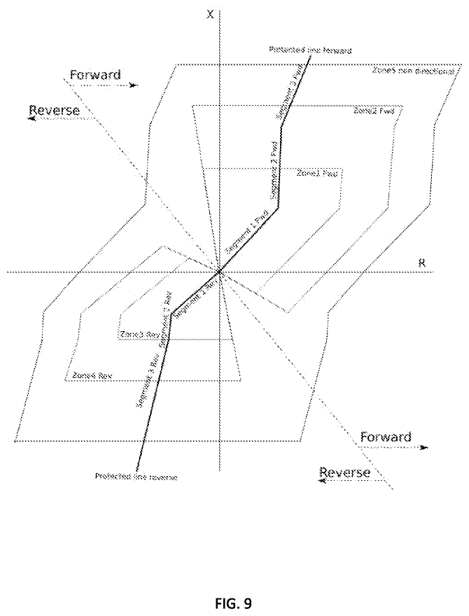

FIG. 9 shows an example of quadrilateral R/X diagram using a method according to embodiments of the invention. In FIG. 9, the characteristics is given with forward reach settings and reverse reach settings. The protected line (solid thick line) is subdivided into a plurality of segments. The segments are represented in FIG. 9 as Segment 1 Forward, Segment 2 Forward, Segment 3 Forward, and Segment 1 Reverse, Segment 2 Reverse, Segment 3 Reverse. To avert significant errors in the protection zone reach precision, it is typical to enforce a maximum resistive reach in terms of the protection zone impedance reach. Suggestions about this can typically be found in the technical protection relay brochures and manuals. However, when configuring a distance relay using the segmented approach as disclosed in the present disclosure, the fault location can be more accurately determined. In particular, as in the segmented method the zone can be set based on the line settings for each of the plurality of segment, for example, to 80% of Segment 1 . . . Segment 3 or directly as kilometers, for example, 78 km from the relaying point, no matter how many segments is included in the line to be protected.

The methods described above in connection with figures may also be carried out in the form of one or more computer process defined by one or more computer programs. This may be, for example, a computer program comprising computer program code means stored in storage medium adapted to perform the method of any of steps, when executed by a computer. The computer program shall be considered to encompass also a module of a computer programs, e.g. the above-described processes may be carried out as a program module of a larger algorithm or a computer process. The computer program(s) may be in source code form, object code form, or in some intermediate form, and it may be stored in a carrier, which may be any entity or device capable of carrying the program. Such carriers include transitory and/or non-transitory computer media, e.g. a record medium, computer memory, read-only memory, electrical carrier signal, telecommunications signal, and software distribution package. Depending on the processing power needed, the computer program may be executed in a single electronic digital processing unit or it may be distributed amongst several processing units.

It will be obvious to a person skilled in the art that, as the technology advances, the inventive concept can be implemented in various ways. The invention and its embodiments are not limited to the examples described above but may vary within the scope of the claims.

1. A method for determining the distance to a fault location of a power line to be protected in an electric power system, the method comprising:
configuring the power line to be protected into a plurality of segments,
obtaining a plurality of line settings separately for each of the plurality of segments configured, and using the line settings obtained to determine the distance to a fault location of the power line to be protected, wherein the line settings include at least one of impedance, resistance, reactance, length, compensation factor, angle.

2. The method according to claim 1, wherein the method comprises:
determining, based on the line settings obtained, the length of each of the plurality of segments configured, in units of length, and determining the distance to the fault location as the sum of the lengths of the plurality of segments.

3. The method according to claim 1, wherein the method comprises:
setting the line settings for each of the plurality of segments configured, for a power line to be protected and/or a protection zone of a power line to be protected, in units of lengths.

4. The method according to claim 1, wherein the method comprises: determining, based on the line settings obtained, the impedance vector, Z=R+iX, separately for each of the plurality of segments configured, and determining the distance to the fault location as the sum of the impedance vectors of the plurality of segments.

5. The method according to claim 1, wherein the step of configuring the power line comprises dividing the power line to be protected into a plurality of segments based the power line type wherein the line type includes at least one of the: overhead line, ground dug cable, type of ground.

6. The method according to claim 1, wherein the method comprises: determining, the phase to earth fault based on the plurality of line settings obtained for each of the plurality of segments configured.

7. The method according to claim 1, wherein the power line comprises at least one protection zone and that said at least one protection zone is divided into a plurality of segments.

8. The method according to claim 1, wherein the power line is a transmission line or a distribution line between two substations and that said transmission line or distribution line is divided into a plurality of segments.

9. A method for configuring an intelligent electronic device to protect a power line of an electric power system, comprising:
receiving, in the intelligent electronic device, a first user input to configure a power line to be protected into a plurality of segments,
identifying the first user input, and based on said identifying, configuring, in the intelligent electronic device, the power line into a plurality of segments,
obtaining, from a user, a plurality of line settings separately for each of the plurality of segments configured, and based on obtaining, using, in the intelligent electronic device, the line settings obtained to determine a fault location of the power line to be protected, wherein the line settings include at least one of impedance, resistance, reactance, length, compensation factor, angle.

10. The method according to claim 9, wherein the method comprises:
determining, in the intelligent electronic device, based on the line settings obtained, the length of each of the plurality of segments configured, in units of length, and determining the distance to the fault location as the sum of the lengths of the plurality of segments.

11. The method according to claim 9, wherein the method comprises: determining, in the intelligent electronic device, based on the line settings obtained, the impedance vector, Z=R+iX, separately for each of the plurality of segments configured, and determining the distance to the fault location as the sum of the impedance vectors of the plurality of segments.

12. The method according to claim 9, wherein the method comprises: determining, in the intelligent electronic device, the phase to earth fault based on the plurality of settings obtained for each of the plurality of segments configured.

13. The method according to claim 9, wherein the method comprises: providing, in the intelligent electronic device, the user with an option to select between a non-segment configuration or a segmented configuration.

14. A non-transitory computer-readable medium on which is stored a computer program comprising computer program code that performs the method of any of claim 1, when the computer program code is executed by a computer.

15. An intelligent electronic device for protecting of a power line of an electric power system, configured by a method of claim 1.

16. A switching arrangement comprising an intelligent electronic device according to claim 15.

17. A non-transitory computer-readable medium on which is stored a computer program comprising computer program code that performs the method of claim 2, when the computer program code is executed by a computer.

18. A non-transitory computer-readable medium on which is stored a computer program comprising computer program code that performs the method of claim 3, when the computer program code is executed by a computer.

19. A non-transitory computer-readable medium on which is stored a computer program comprising computer program code that performs the method of claim 4, when the computer program code is executed by a computer.

20. A non-transitory computer-readable medium on which is stored a computer program comprising computer program code that performs the method of claim 5, when the computer program code is executed by a computer.
